(19) United States
(12) Patent Application Publication
(10) Pub. No.: US 2020/0154569 A1
(43) Pub. Date: May 14, 2020

(54) POSITIONING STRUCTURE

(71) Applicant: PEGATRON CORPORATION, Taipei City (TW)

(72) Inventors: HUNG-YUN WU, TAIPEI CITY (TW); HUI-CHEN WANG, TAIPEI CITY (TW); YI-CHUN TANG, TAIPEI CITY (TW); HSIAO-FAN CHEN, TAIPEI CITY (TW); CHING-YEN HUANG, TAIPEI CITY (TW)

(21) Appl. No.: 16/449,538

(22) Filed: Jun. 24, 2019

(30) Foreign Application Priority Data
Nov. 8, 2018 (TW) 107139672

(51) Int. Cl. H05K 1/14

(52) U.S. Cl. CPC H05K 1/144; H01R 12/722

(57) ABSTRACT

The present invention discloses a positioning structure, including: a first substrate, a bonding member, a positioning member, and a first fixing member. The first substrate includes a first through hole. The bonding member is disposed between the first substrate and the positioning member to bond the first substrate and the positioning member, a position of the bonding member being corresponding to the first through hole. The first fixing member is fixed in the positioning member via the first through hole of the first substrate, to fix the positioning member on the first substrate.

### BACKGROUND

### Technical Field

The disclosure relates to a positioning structure, and in particular, to a positioning structure capable of increasing bondability between a positioning member and a substrate.

### Related Art

First, in the prior art, a surface mount technology (SMT) is usually utilized to dispose a nut (or referred to as a bolt) on a printed circuit board, so as to accelerate the disposing of the nut. Meanwhile, by disposing a plurality of nuts, another printed circuit board may be further disposed on the printed circuit board with a plurality of nuts been disposed on, to form a stacked printed circuit board assembly.

However, in the existing manner of disposing the nut using the surface mount technology, bonding is performed only through soldering, and mostly, bondability between the nut and the printed circuit board needs to be further improved through dispensing or increasing soldering on a side edge of a contact position between the nut and the printed circuit board. However, in a relatively strict military falling test, even if the foregoing manner of dispensing or increasing soldering is utilized, an impact of the falling test still cannot be withstood, leading the nut to separate from the printed circuit board.

### SUMMARY

In order to resolve the foregoing technical problem, a technical solution used in the disclosure is to provide a positioning structure, including: a first substrate, a bonding member, a positioning member, and a first fixing member. The first substrate includes a first through hole. The bonding member is disposed between the first substrate and the positioning member to bond the first substrate and the positioning member, a position of the bonding member being corresponding to the first through hole. The first fixing member is fixed in the positioning member via the first through hole of the first substrate, to fix the positioning member on the first substrate. A beneficial effect of the positioning structure provided in the disclosure is that in the positioning structure, the positioning member can be fixed on the first substrate through fixing the first fixing member in the positioning member, thereby increasing bondability between the positioning member and the first substrate.

In order to further understand features and technical content of the disclosure, please refer to the following detailed description and drawings related to the disclosure. However, the provided drawings are merely used for reference and description, but not intended to limit the disclosure.

### BRIEF DESCRIPTION OF THE DRAWINGS

FIG. 1 is a schematic three-dimensional combined view of a positioning structure according to an embodiment of the disclosure.

FIG. 2 is another schematic three-dimensional combined view of a positioning structure according to an embodiment of the disclosure.

FIG. 3 is a schematic three-dimensional exploded view of a positioning structure according to an embodiment of the disclosure.

FIG. 4 is another schematic three-dimensional exploded view of a positioning structure according to an embodiment of the disclosure.

FIG. 5 is a cross-sectional view of a V-V cutting line of FIG. 1.

FIG. 6 is a partial cross-sectional exploded view of a positioning structure according to an embodiment of the disclosure.

FIG. 7 is a partial cross-sectional exploded view of another implementation of a positioning structure according to an embodiment of the disclosure.

### DETAILED DESCRIPTION

The following describes implementations related to a “positioning structure” that are disclosed in the present invention through particular embodiments, and those skilled in the art can understand advantages and effects of the disclosure from content disclosed in this specification. The disclosure may be implemented or applied through other various specific embodiments, and various modifications and changes may be made to details in this specification based on different opinions and applications without departing from a spirit and scope of the disclosure. In addition, it is announced in advance that drawings of the disclosure are merely illustrative but not delineated according to actual sizes. The following implementations will further describe in detail related technical content of the disclosure, but the disclosed content is not intended to limit the protection scope of the disclosure.

It should be understood that, although terms “first,” “second,” and “third,” etc. may be used herein to describe various elements, these elements should not be limited by these terms. These terms are mainly used to distinguish one element from another element. In addition, the term “or” used herein may include any one or a combination of more of associated listed items depending on an actual situation.

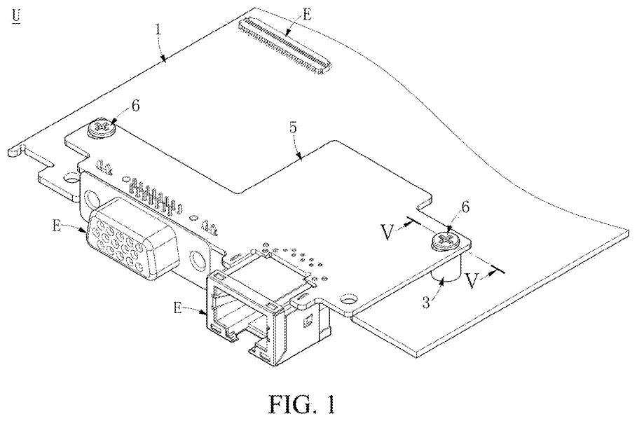

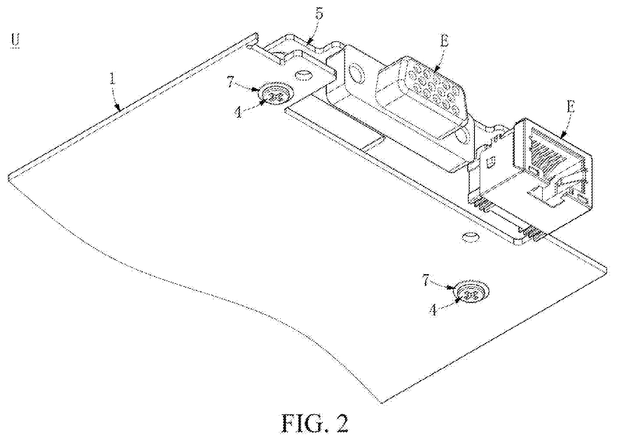

First, referring to FIG. 1 and FIG. 2, FIG. 1 and FIG. 2 each is a schematic three-dimensional combined view of a positioning structure according to an embodiment of the disclosure. The disclosure provides a positioning structure U, including a first substrate 1, a positioning member 3, and a first fixing member 4. With respect to embodiments of the disclosure, bondability between the first substrate 1 and the positioning member 3 can be increased by disposing the first fixing member 4. Further, the positioning structure U may further include a second substrate 5 and a second fixing member 6. The second substrate 5 may be disposed on the positioning member 3, so that the second substrate 5 is stacked on the first substrate 1, and the second substrate 5 is fixed on the positioning member 3 with the second fixing member 6. In addition, for example, the first substrate 1 and the second substrate 5 each may be a printed circuit board. The first substrate 1 can be implemented by a main printed circuit board, and the second substrate 5 can be implemented by a secondary circuit board, but the disclosure is not limited thereto.

As described above, the positioning member 3 (or may be referred to as a nut) disposed between the first substrate 1 and the second substrate 5 may be configured to isolate the first substrate 1 from the second substrate 5, so as to prevent electronic components E disposed on the first substrate 1 and the second substrate 5 from interfering with each other. Meanwhile, in other embodiments, the positioning member 3 may also provide a grounding function for the first substrate 1 and the second substrate 5, but the disclosure is not limited thereto. In addition, the second substrate 5 may be disposed in a stacking manner on the first substrate 1 via one or more positioning members 3.

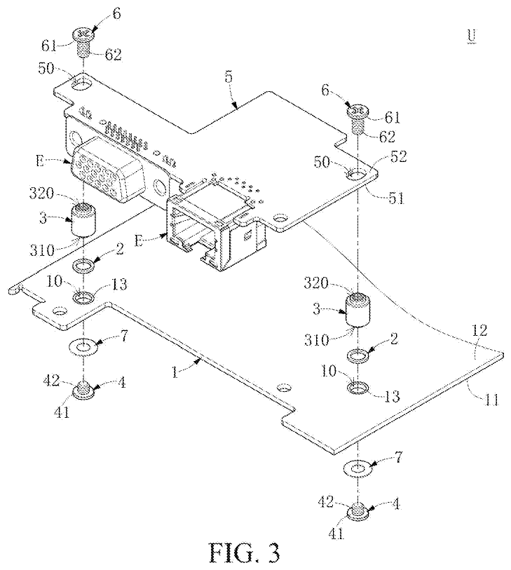

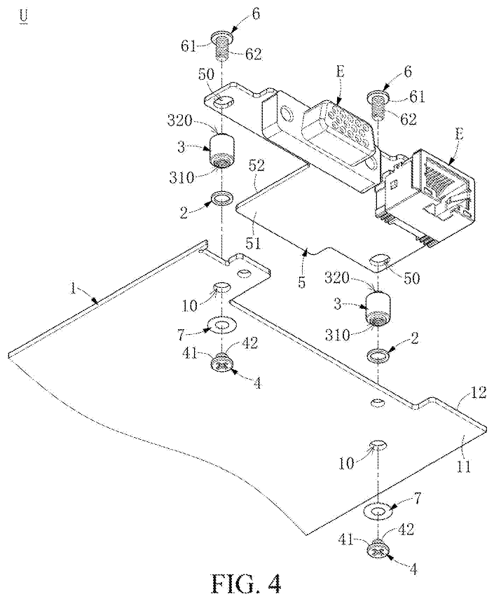

Referring to FIG. 3 and FIG. 4 together, FIG. 3 and FIG. 4 each is a schematic three-dimensional exploded view of a positioning structure according an embodiment of the disclosure. As shown in FIG. 3 and FIG. 4, the positioning structure U further includes a bonding member 2, in which the bonding member 2 is disposed between the first substrate 1 and the positioning member 3 to bond the first substrate 1 and the positioning member 3, so that the positioning member 3 is adhered to the first substrate 1. In some embodiments, the bonding member 2 may be solder, for example but not limited to soldering tin or solder paste. In other embodiments, the bonding member 2 may be an adhesive, and the adhesive may include, for example but be not limited to gel or a bonding agent.

As shown in FIG. 3 and FIG. 4, the first substrate 1 includes a first surface 11 (that is, a lower surface of the first substrate 1), a second surface 12 (that is, an upper surface of the first substrate 1) corresponding to the first surface 11, and a first through hole 10 passing through the first surface 11 and the second surface 12. In this embodiment, the bonding member 2 may be disposed on the second surface 12 of the first substrate 1, and a position of the bonding member 2 is corresponding to the first through hole 10. For example, the bonding member 2 may be disposed adjacent to the first through hole 10. Preferably, the bonding member 2 is disposed around the first through hole 10, but the disclosure is not limited thereto.

In some embodiments, in order to dispose the positioning member 3 on the first substrate 1 by using a surface mount technology, the first substrate 1 further includes a pad 13. The pad 13 may be disposed in correspondence to the first through hole 10; for example, the pad 13 may be disposed adjacent to the first through hole 10. Preferably, the pad 13 may be disposed around the first through hole 10. The bonding member 2 may thereby be disposed on the pad 13 of the first substrate 1, and the positioning member 3 is further disposed on the bonding member 2, so as to solder the positioning member 3 on to the first substrate 1 by using a manufacture procedure of the surface mount technology. It should be noted that although the foregoing embodiment takes the bonding member 2 being solder as an example, the disclosure is not limited thereto.

In some embodiments, the positioning member 3 includes a first positioning hole 310 corresponding to the first through hole 10. In particular, the first fixing member 4 is fixed in the positioning member 3 via the first through hole 10 of the first substrate 1, to fix the positioning member 3 on the second surface 12 of the first substrate 1. In some embodiments, the first fixing member 4 includes a first abutting portion 41 abutting against the first surface 11 of the first substrate 1 and a first screw jointing portion 42 disposed in the first positioning hole 310 of the positioning member 3. The first screw jointing portion 42 of the first fixing member 4 may thereby be screwed into the first positioning hole 310 of the positioning member 3, to fix the positioning member 3 on the second surface 12 of the first substrate 1, thereby further increasing bondability between the first substrate 1 and the positioning member 3.

In some embodiments, the first fixing member 4 may be a screw jointing member, for example but not limited to a screw, the first screw jointing portion 42 may be an external thread of the screw, and the first positioning hole 310 of the positioning member 3 may preferably have an internal thread (not labelled) corresponding to the first screw jointing portion 42.

In some embodiments, preferably, the positioning structure U may further include a washer 7. The washer 7 may be disposed between the first abutting portion 41 of the first fixing member 4 and the first substrate 1, and the first abutting portion 41 abuts against the first substrate 1 through the washer 7 to prevent the first fixing member 4 and the first substrate 1 from being worn by each other. For example, the washer 7 may be a flat washer, a spring washer, or a locking washer, but the disclosure is not limited thereto.

In some embodiments, as shown in FIG. 3 and FIG. 4, the second substrate 5 includes a third surface 51 (that is, a lower surface of the second substrate 5), a fourth surface 52 (that is, an upper surface of the substrate 5) corresponding to the third surface 51, and a second through hole 50 passing through the third surface 51 and the fourth surface 52.

In some embodiments, the positioning member 3 includes a second positioning hole 320 corresponding to the second through hole 50. In particular, the second fixing member 6 is fixed in the positioning member 3 via the second through hole 50 of the second substrate 5 to fix the positioning member 3 on the third surface 51 of the second substrate 5.

In some embodiments, the second fixing member 6 includes a second abutting portion 61 abutting against the fourth surface 52 of the second substrate 5 and a second screw jointing portion 62 disposed in the second positioning hole 320 of the positioning member 3. The second screw jointing portion 62 of the second fixing member 6 may thereby be screwed into the second positioning hole 320 of the positioning member 3, to fix the positioning member 3 on the third surface 51 of the second substrate 5.

In some embodiments, the second fixing member 6 may be a screw jointing member, for example but not limited to a screw, and the second screw jointing portion 62 may be an external thread of the screw, and the second positioning hole 320 of the positioning member 3 may preferably have an internal thread (not labelled) corresponding to the second screw jointing portion 62. In addition, it should be noted that, in other embodiments, a washer (not shown) may be further included between the second abutting portion 61 of the second fixing member 6 and the second substrate 5, but the disclosure is not limited thereto. The second substrate 5 may thereby be disposed on the first substrate 1 in a stacking manner.

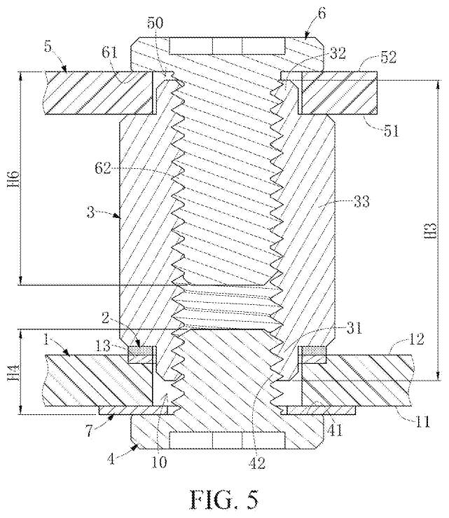

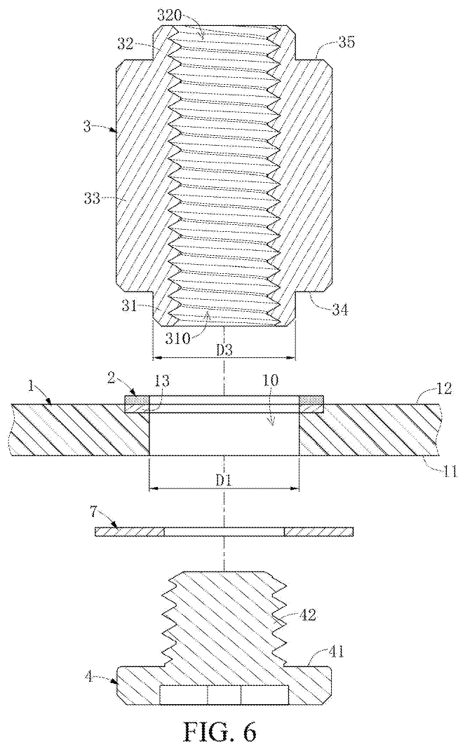

Next, referring to FIG. 5 and FIG. 6 together, FIG. 5 is a cross-sectional view of a V-V cutting line of FIG. 1, and FIG. 6 is a partial cross-sectional exploded view of a positioning structure according to an embodiment of the disclosure. As shown in FIG. 5, the positioning member 3 includes a first end 31, a second end 32, and a connecting portion 33 connected between the first end 31 and the second end 32. The first end 31 has a first positioning hole 310, and the second end 32 has a second positioning hole 320. In addition, it should be noted that although the first positioning hole 310 and the second positioning hole 320 in the figures are embodiments that are connected to each other as an example, in other embodiments, the first positioning hole 310 and the second positioning hole 320 may also be blind holes, and the disclosure is not limited thereto.

In some embodiments, as shown in FIG. 5, a sum of a predetermined height H4 of the first screw jointing portion 42 of the first fixing member 4 and a predetermined height H6 of the second screw jointing portion 62 of the second fixing member 6 is less than a predetermined height H3 of the positioning member 3, so that the first abutting portion 41 of the first fixing member 4 fits the washer 7, and the second abutting portion 62 of the second fixing member 6 fits the second substrate 5, but the disclosure is not limited thereto.

In some embodiments, as shown in FIG. 5 and FIG. 6, the first end 31 of the positioning member 3 may be disposed in the first through hole 10, that is, the first through hole 10 has a predetermined inner diameter D1, and the first end 31 has a predetermined outer diameter D3, in which the predetermined outer diameter D3 of the first end 31 is smaller than the predetermined inner diameter D1 of the first through hole 10, so that the positioning member 3 can be fixed in the first through hole 10.

In some embodiments, the positioning member 3 further includes a first abutting end 34. The bonding member 2 may be disposed between the first abutting end 34 and the first substrate 1, and the first abutting end 34 abuts against the second surface 12 of the first substrate 1 via the bonding member 2. The first end 31 of the positioning member 3 may thereby be first disposed in the first through hole 10 before the positioning member 3 is bonded to the first substrate 1 through welding, and may abut against the second surface 12 of the first substrate 1 by using the first abutting end 34, so that the positioning member 3 achieves pre-alignment relative to the first substrate 1. In addition, the first abutting end 34 is located between the first end 31 and the connecting portion 33, but the disclosure is not limited thereto.

In other embodiments, the positioning member 3 further includes a second abutting end 35, and the second abutting end 35 is located between the second end 32 and the connecting portion 33. Since the purpose of the second abutting end 35 is similar to that of the first abutting end 34, details are not be described herein again.

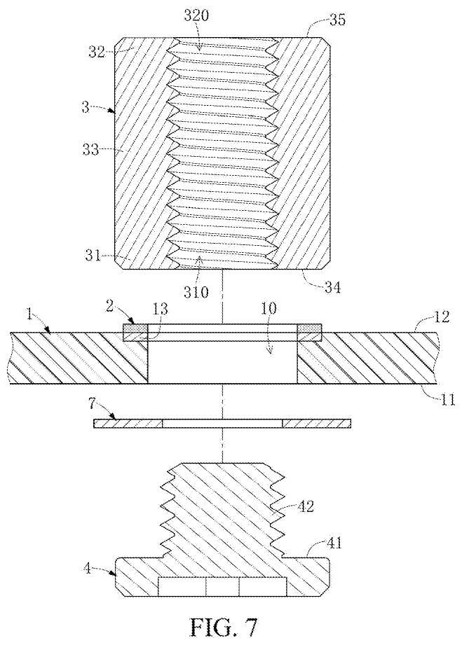

As described above, referring to FIG. 7, FIG. 7 is a partial cross-sectional exploded view of another embodiment of a positioning structure according to an embodiment of the disclosure. It can be learned from a comparison between FIG. 7 and FIG. 6 that, in the embodiment of FIG. 7, the first end 31 and the second end 32 of the positioning member 3 may not be disposed in the first through hole 10 and the second through hole 50. In other words, with respect to the embodiment of FIG. 7, the first abutting end 34 may be at the first end 31, the second abutting end 35 may be at the second end 32, and the first abutting end 34 and the second abutting end 35 abut against the second surface 12 of the first substrate 1 and the third surface 51 of the second substrate 5 respectively. However, it should be noted that, with respect to the embodiments of the disclosure, the embodiment of FIG. 6 is better than the embodiment of FIG. 7.

In some embodiments, a predetermined outer diameter (not labelled) of the second end 32 of the positioning member 3 may be smaller than a predetermined inner diameter (not labelled) of the second through hole 50, so that the second end 32 of the positioning member 3 can be disposed in the second through hole 50 of the second substrate 5. Further, before the positioning member 3 is fixed on the second substrate 5 by using the second fixing member 6, the second end 32 of the positioning member 3 may be first disposed in the second through hole 50 of the second substrate 5, and the second abutting end 35 of the positioning member 3 abuts against the third surface 51 of the second substrate 5, so that the second substrate 5 can be aligned on the positioning member 3.

In summary, in the positioning structure U provided in the disclosure, the first fixing member 4 can be fixed in the positioning member 3 via the first through hole 10 of the first substrate 1, to increase bondability between the positioning member 3 and the first substrate 1.

Further, when the bonding member 2 is solder, the positioning member 3 may be disposed on the first substrate 1 by using the surface mount technology. Meanwhile, the positioning member 3 can be further combined with the first substrate 1 firmly using the first fixing member 4. In other words, in the positioning structure U provided in the embodiments of the disclosure, not only the positioning member 3 can be soldered on the first substrate 1 using solder, but also the bondability between the positioning member 3 and the first substrate 1 can be increased with the disposed first fixing member 4.

Further, with disposing the first through hole 10, the first fixing member 4 disposed along a direction of the first surface 11 of the first substrate 1 and the positioning member 3 disposed along a direction of the second surface 12 of the first substrate 1 can be bonded with each other, to combine the positioning member 3 with the first substrate 1 firmly.

Since the content described above is merely preferred feasible embodiments of the disclosure, but do not hereby limit claims of the disclosure, all equivalent technical changes made utilizing the specification and the drawings of the disclosure are included in the claims of the disclosure.

What is claimed is:

1. A positioning structure, comprising:
a first substrate, comprising a first through hole;
a positioning member;
a bonding member disposed between the first substrate and the positioning member to bond the first substrate and the positioning member, a position of the bonding member being corresponding to the first through hole; and
a first fixing member fixed in the positioning member via the first through hole of the first substrate, to fix the positioning member on the first substrate.

2. The positioning structure according to claim 1, wherein the positioning member comprises a first positioning hole with a position corresponding to the first through hole, the first fixing member comprising a first abutting portion abutting against the first substrate and a first screw jointing portion disposed in the first positioning hole of the positioning member, and the first fixing member being screwed into the first positioning hole of the positioning member via the first screw jointing portion, to fix the positioning member on the first substrate.

3. The positioning structure according to claim 2, further comprising: a second substrate and a second fixing member, the second substrate comprising a second through hole, the fixing member comprising a second positioning hole corresponding to the second through hole, and the second fixing member comprising a second abutting portion abutting against the second substrate and a second screw jointing portion disposed in the second positioning hole of the fixing member, wherein the second screw jointing portion of the second fixing member is screwed into the second positioning hole of the positioning member to fix the positioning member on the second substrate.

4. The positioning structure according to claim 3, wherein a sum of a predetermined height of the first screw jointing portion of the first fixing member and a predetermined height of the second screw jointing portion of the second fixing member is less than a predetermined height of the positioning member.

5. The positioning structure according to claim 3, wherein the positioning member further comprises a first abutting end and a second abutting end corresponding to the first abutting end, the bonding member is disposed between the first abutting end and the first substrate, the first abutting end abuts against the first substrate through the bonding member, and the second abutting end abuts against the second substrate.

6. The positioning structure according to claim 1, wherein the positioning member comprises a first end, a second end, and a connecting portion connected between the first end and the second end, the first end has a first positioning hole, and the second end has a second positioning hole.

7. The positioning structure according to claim 6, wherein the first through hole has a predetermined inner diameter, the first end has a predetermined outer diameter, and the predetermined outer diameter is smaller than the predetermined inner diameter.

8. The positioning structure according to claim 1, further comprising: a washer disposed between a first abutting portion of the first fixing member and the first substrate, and the first abutting portion abutting against the first substrate through the washer.

9. The positioning structure according to claim 1, wherein the first substrate further comprises a pad disposed corresponding to the first through hole, and the bonding member is disposed on the pad of the first substrate.

10. The positioning structure according to claim 1, wherein the bonding member is solder.
